(19) United States
(12) Patent Application Publication
(10) Pub. No.: US 2026/0229843 A1
(43) Pub. Date: Aug. 6, 2026

(54) III-V SEMICONDUCTOR DEVICE, ASSEMBLY, AND METHOD

(71) Applicant: Innolume GmbH, Dortmund (DE)

(72) Inventors: Alexey Gubenko, Dortmund (DE); Alexey Kovsh, Dortmund (DE); Artem Petrenko, Dortmund (DE); Aleksei Borodkin, Dortmund (DE); Vladislav Bougrov, Dortmund (DE)

(21) Appl. No.: 19/046,917

(22) Filed: Feb. 6, 2025

(51) Int. Cl. H01S 5/125; H01S 5/0225; H01S 5/34; H01S 5/343

(52) U.S. Cl. CPC H01S 5/125; H01S 5/0225; H01S 5/341; H01S 5/343

(57) ABSTRACT

A photonic III-V semiconductor device comprises at least one distributed feedback (DFB) laser diode having a laser active region, and at least one semiconductor optical amplifier (SOA) having an amplifier active region. The III-V semiconductor device comprises a III-V semiconductor heterostructure formed on a III-V semiconductor substrate, the III-V semiconductor heterostructure comprising an active layer structure between a lower cladding layer and an upper cladding layer; the active layer structure forming the laser active region and the amplifier active region. The device has an optical interface edge. The at least one DFB laser diode comprises an optical output facet, and the at least one SOA comprises an optical input facet. The at least one DFB laser diode and the at least one SOA are positioned in parallel with the output facet and the input facet lying on the optical interface edge.

### BACKGROUND

In data communication, optical data communication technology may provide an overall excellent performance, for example, from the space-efficiency and/or the cost-efficiency points of view. High-quality photonic semiconductor devices comprising, for example, laser diodes and semiconductor optical amplifiers may be manufactured of III-V semiconductors.

An important factor affecting the feasibility of various optical components and devices for optical data communication is the size or footprint thereof. The form factor of many data transfer systems is standardized, and the space available for the optical components and devices may be very limited.

On the other hand, there is a requirement to keep the manufacturing costs of the optical components and devices low.

In addition to data communication applications, corresponding challenges related to device manufacturing and/or assembly may be present in other applications such as in optical sensing.

Both the limited space and the low-cost requirement raise a continuous need for developing integrated solutions where those aspects are properly taken into account.

### SUMMARY

This summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In a first aspect, a photonic III-V semiconductor device is disclosed. The photonic III-V semiconductor device comprises at least one distributed feedback (DFB) laser diode having a laser active region, and at least one semiconductor optical amplifier (SOA) having an amplifier active region. The III-V semiconductor device comprises a III-V semiconductor heterostructure formed on a III-V semiconductor substrate. The III-V semiconductor heterostructure comprises an active layer structure between a lower cladding layer and an upper cladding layer. The active layer structure forms the laser active region and the amplifier active region.

The photonic III-V semiconductor device has an optical interface edge. The at least one DFB laser diode comprises an optical output facet, and the at least one SOA comprises an optical input facet. The at least one DFB laser diode and the at least one SOA are positioned in parallel with the output facet and the input facet lying on the optical interface edge.

In an embodiment, the III-V semiconductor heterostructure further comprises a cap layer on the upper cladding layer. Further, the at least one DFB laser diode has at least one surface corrugated grating configured to serve as a distributed Bragg reflector (DBR). The at least one SOA has at least one ridge waveguide. The surface corrugated grating(s) and the ridge waveguide(s) are formed in the cap layer.

In an embodiment of the first aspect, which may be in accordance with the previous embodiment, the ridge waveguide comprises at least one bent section.

In an embodiment of the first aspect, which may be in accordance with any of the previous embodiments, the semiconductor device comprises a cap layer on the upper cladding layer, the lower cladding layer has a lower cladding refractive index, the upper cladding layer has an upper cladding refractive index, and the cap layer has a cap refractive index higher than the lower cladding refractive index and the upper cladding refractive index.

In an embodiment of the first aspect, which may be in accordance with any of the previous embodiments, the active layer structure comprises at least one quantum structure layer comprising at least one quantum well, quantum dots, quantum wires, and/or quantum dashes.

In an embodiment of the first aspect, which may be in accordance with any of the previous embodiments, the III-V semiconductor comprises gallium arsenide GaAs; the active layer structure comprises indium arsenide InAs and/or indium gallium arsenide InGaAs, the lower cladding layer comprising AlGaAs, and the upper cladding layer comprising AlGaAs.

In an embodiment of the first aspect, which may be in accordance with any of the previous embodiment, the active layer structure comprises at least one quantum structure layer comprising indium arsenide InAs, gallium arsenide GaAs, and/or indium gallium arsenide InGaAs.

In an embodiment of the first aspect, which may be in accordance with the previous embodiment, the at least one quantum structure layer comprises at least one layer of quantum dots.

In an embodiment of the first aspect, which may be in accordance with any of the two previous embodiments, the at least one layer of quantum dots comprises a plurality of superposed layers of quantum dots.

In an embodiment of the first aspect, which may be in accordance with the previous embodiment, the quantum dots of different layers of the plurality of superposed layers of quantum dots may have different size distributions.

In an embodiment of the first aspect, which may be in accordance with any of the previous embodiments, the at least one DFB laser diode comprises an array of a plurality of DFB laser diodes.

In an embodiment of the first aspect, which may be in accordance with the previous embodiment, the laser active region is configured to generate light at a wavelength range. Further, each of the DFB laser diodes of the plurality of DFB laser diodes has at least one surface corrugated grating configured to serve as a distributed Bragg reflector (DBR), configured to produce a maximum reflectance at a center wavelength differing from the center wavelengths at which the surface corrugated grating(s) of each of the other DFB laser diodes of the plurality of DFB laser diodes produces its maximum reflectance. The surface corrugated gratings may be considered selecting the center wavelengths to be transmitted out of the laser diode. The at least one SOA is configured to amplify each of the center wavelengths.

In a second aspect, an optical assembly is disclosed. The optical assembly comprises a photonic III-V semiconductor device in accordance with the first aspect or any of its embodiments, and an optical coupling element having a first coupling surface and an opposite second coupling surface, the first coupling surface being faced towards the optical interface edge. The optical coupling element comprises at least one first waveguide configured and positioned to receive light transmitted out of the optical output facet(s) and transmit it from the first coupling surface to the second coupling surface and thereby out of the optical coupling element. The optical coupling element further comprises at least one second waveguide configured and positioned to receive light and transmit it from the second coupling surface to the first coupling surface and thereby out of the optical waveguide to the optical input facet(s).

In an embodiment of the second aspect, the at least one DFB laser diode comprises an array of a plurality of DFB laser diodes, and the at least one first waveguide comprises a plurality of first waveguides.

In an embodiment of the second aspect, which may be in accordance with the previous embodiment, the optical coupling element comprises a combiner configured to combine two or more of the plurality of first waveguides.

In an embodiment of the second aspect, which may be in accordance with any of the previous embodiments, the optical assembly further comprises a photonic integrated circuit (PIC) configured and positioned to receive the light transmitted out of the optical coupling element by the first waveguide(s), and to transmit it back to the optical coupling element to the second waveguide(s) thereof.

In a third aspect, an optical transceiver or an optical engine is disclosed, the optical transceiver or the optical engine comprising an optical assembly in accordance with the second aspect or any of its embodiments.

In a fourth aspect, a method is disclosed for manufacturing a photonic III-V semiconductor device comprising at least one distributed feedback (DFB) laser diode having a laser active region, and at least one semiconductor optical amplifier (SOA) having an amplifier active region. The method comprises the operation of depositing, on a III-V semiconductor substrate, a III-V semiconductor heterostructure comprising an active layer structure superposed between a lower cladding layer and an upper cladding layer.

The method is carried out such that the active layer structure forms the laser active region and the amplifier active region; the photonic semiconductor device has an optical interface edge, the at least one DFB laser diode comprises an optical output facet, and the at least one SOA comprises an optical input facet.

The at least one DFB laser diode and the at least one SOA are manufactured so as to be positioned in parallel with the output facet and the input facet lying on the optical interface edge.

In an embodiment of the fourth aspect, the method comprises the operations of depositing a cap layer on the upper cladding layer; and forming, in the cap layer, at least one surface corrugated grating configured to serve as a distributed Bragg reflector (DBR) for the at least one DFB laser diode, and at least one ridge waveguide for the at least one SOA.

In an embodiment of the fourth aspect, which may be in accordance with any of the previous embodiments, the at least one DFB laser comprises and array of a plurality of DFB lasers.

Further embodiments may be implemented in accordance with the claims.

Many of the attendant features will be more readily appreciated as the same becomes better understood by reference to the following detailed description considered in connection with the accompanying drawings.

### BRIEF DESCRIPTION OF THE DRAWINGS

The present description will be better understood from the following detailed description read in view of the accompanying drawings, wherein:

FIG. 1 shows a cross-sectional view and a top view of a part of a photonic III-V semiconductor device;

FIG. 2 shows a cross-sectional view of a layer structure of a photonic semiconductor device;

FIGS. 3 and 4 shows top views of optical assemblies; and

FIG. 5 shows a flow chart of a method for manufacturing a photonic III-V semiconductor device.

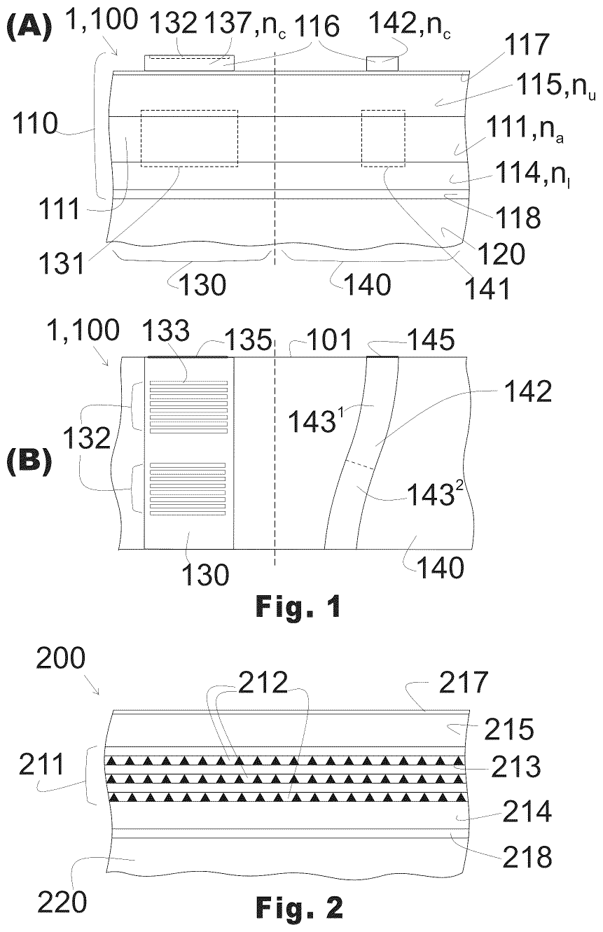

The drawings of FIGS. 1 to 4 are schematic illustrations of three-dimensional entities. They are not drawn to scale.

### DETAILED DESCRIPTION

The detailed description provided below in connection with the appended drawings is intended as a description of a number of embodiments and is not intended to represent the only forms in which the embodiments may be constructed, implemented, or utilized.

One or more of the embodiments specified above and/or hereinafter may advantageously provide photonic III-V semiconductor devices having one or more laser diodes and one or more semiconductor optical amplifiers (SOA) integrated in the same photonic semiconductor device. Such integrated semiconductor devices may have a small footprint defined by the actual dimensions of the laser diode(s) and the SOA(s) only. Such a small footprint device may enable the integrated semiconductor device to be used in small-size optical devices, such as optical transceivers or optical engines, having only a limited space available for the photonic semiconductor devices. Further, the laser diode(s) and the SOA(s) of the integrated photonic semiconductor devices may advantageously be manufactured in a simple manufacturing process implementable using a single epitaxial growth process without any additional growth operations, such as an overgrowth.

A “III-V semiconductor device” refers to a semiconductor device where at least part of the operational semiconductor parts of the device comprises, or is formed of, one or more semiconductors of column III and column V materials, thus one or more III-V semiconductor materials. Examples of such III-V semiconductors comprise gallium arsenide GaAs and its derivatives such as indium gallium arsenide InGaAs and aluminum gallium arsenide AlGaAs. Correspondingly, a “III-V semiconductor element”, such as a layer or a layer structure, refers to an element comprising, or being formed of, one or more semiconductors of column III and column V materials.

The photonic III-V semiconductor device 100 of FIG. 1 may form a part of an optical device or apparatus, such as an optical transceiver 1.

Hereinafter, the photonic III-V semiconductor device 100 is also referred to as “the photonic semiconductor device”.

The photonic semiconductor device 100 has a distributed feedback (DFB) laser diode 130 and a semiconductor optical amplifier (SOA) 140.

In the drawings A) and B) of FIG. 1, one DFB laser diode 130 and one SOA 140 of the photonic semiconductor device are shown. The photonic semiconductor device may further comprise other DFB laser diodes. Then, a plurality of DFB laser diodes may be arranged in an array.

The semiconductor device 100 is formed on a common III-V semiconductor substrate 120. The DFB laser diode 130 and the SOA 140 are thereby integrated into the same device 100.

The III-V semiconductor substrate 120 on which the heterostructure is formed may comprise, or be formed of, GaAs and/or one or more of its derivatives.

The DFB laser diode 130 comprises an active region, hereinafter called a laser active region 131. The SOA 140 comprises an active region, hereinafter called an amplifier active region 141.

An “active” region of a photonic component such as a laser diode or a SOA may refer to a region where the core operation(s) of the photonic component take/takes place. In a laser diode and a SOA, such operations may comprise, for example, stimulated emission of radiation and light amplification, respectively.

The photonic semiconductor device 100 comprises a III-V semiconductor heterostructure 110, hereinafter referred to also as “the heterostructure”.

A “heterostructure” refers to a semiconductor structure comprising two or more different semiconductor materials. The different materials may form or be in the form of layers, whereby layers of different materials are superposed. A III-V semiconductor heterostructure may comprise, for example, a plurality of layers of different materials selected from GaAs and its derivatives.

The heterostructure 110 comprises an active layer structure 111 between a lower cladding layer 114 and an upper cladding layer 115.

The lower and upper cladding layers 114, 115 may contribute, for example, to formation of a waveguide. They may also contribute to distribution of the electrical current in the device structure.

Each of the lower and upper cladding layers may be formed as a multi-layer structure comprising a plurality of cladding sub-layers. Such cladding sub-layers may differ from each other, for example, by the material composition and/or the doping thereof.

The active layer structure 111 forms the laser active region 131 and the amplifier active region 141.

Thereby, the active layer structure 111 forms a common active layer structure shared by the DFB laser diode 130 and the SOA 140.

Due to the common substrate 120 and the common active layer structure 111 of the DFB laser diode 130 and the SOA 140, the photonic semiconductor device 110 may be considered forming a monolithically integrated photonic semiconductor device configuration.

The photonic semiconductor device has an optical interface edge 101. The optical interface edge may comprise, form, or be formed by, a side surface of the photonic semiconductor device. “Optical interface edge” refers to that the photonic semiconductor device may be optically connected or coupled to another device or module such that the optical connection or coupling is formed via or by the optical interface edge 101.

The DFB laser diode 130 comprises an optical output facet 135 which lies on the optical interface edge 101. The SOA 140 comprises an optical input facet 145 which lies on the optical interface edge 101.

A “facet” refers to a transmitting or receiving area on
a surface for transmitting and/or receiving light, respectively. The light emitted by the DFB laser diode 130 may thus be transmitted out of the DFB laser via or through the output facet 135. Correspondingly, light can enter, or be transmitted into, the SOA via or through the optical input facet 145.

In the example of FIG. 1, the DFB laser diode 130 and the SOA 140 thereby lie in parallel.

In other embodiments, monolithically integrated photonic device configurations may be implemented where a DFB laser diode and a SOA lie in series or in a daisy chain configuration such that the optical output facet of a DFB laser diode and the optical input facet of an SOA face each other.

The heterostructure comprises further a cap layer 116 on the upper cladding layer 115.

A layer lying or being formed “on” another layer or structure refers to the layer in question and the other layer or structure overlapping at least partially. The layer and the other layer of structure may be in contact. Alternatively, there may be one or more intermediate layers or structures therebetween.

In the example of FIG. 1, there is such intermediate layer which may serve as a stop layer 117 as discussed below. Other embodiments may be implemented without a stop layer.

In the example of FIG. 1, the cap layer is patterned both in the DFB laser diode and in the SOA so as to form an elongated ridge structure 137, 142. In other embodiments, the cap layer of a photonic semiconductor structure may form a continuous layer through the width of the DFB laser diode.

Ridge structures may be manufactured in a cap layer by first epitaxially depositing or growing the cap layer on the stop layer. With a suitable material, such as for example GaP (Gallium Phosphide) or InGaP (Indium Gallium Phosphide) selected for the stop layer 117, the cap layer 116 may then be etched away outside the ridge structures, the etching being stopped at the stop layer.

The DFB laser diode 130 of FIG. 1 comprises a pair of distributed Bragg reflectors (DBR) in the form of surface corrugated gratings 132 formed in the cap layer 116. Each DBR comprises a grating formed by an array of grooves 133 or indentations which may have been formed in the cap layer, for example, by etching.

A DBR in the form of a surface corrugated grating refers to a surface corrugated grating which is configured to serve as a distributed Bragg reflector.

In other embodiments, the heterostructure of a DFB laser diode may comprise one or two such surface corrugated gratings, which may be formed in any appropriate layer by etching or any other appropriate process(es).

The ridge structure of the SOA 140 is formed as a ridge waveguide 142. As illustrated in the top view of FIG. 1, the ridge waveguide comprises two bent sections 143¹, 143² with opposite directions of curvature, the two bent sections thereby forming an S-shaped ridge waveguide.

A “bent” section refers to a curved part, thus a “curved” section, of a ridge waveguide.

In other embodiments, a ridge waveguide of the SOA of a photonic semiconductor device may comprise one or more bent sections with any appropriate curvature configuration(s). A ridge waveguide with at least one bent section may comprise one or more straight sections. With a ridge waveguide having one or more bent sections, the length of the ridge waveguide and thereby the amplification achievable may advantageously be higher than in the case of a SOA with a similar width and a straight ridge waveguide.

A SOA with a bent section may be called a bent SOA.

The SOA 140 of the example of FIG. 1 comprises one ridge waveguide 142. In other embodiments, photonic semiconductor devices may be implemented which comprise a plurality of ridge waveguides in accordance with any of those discussed above the active layer structure. Then, a plurality of SOAs may be considered being formed, each having an amplifier active region below it.

The active layer structure may be a multi-layer structure comprising a plurality of active layers. Such active layers may differ from each other, for example, by the material composition and/or the doping thereof. The properties of one or more of the active layers may be selected to provide a quantum well in the active layer structure. One or more of the active layers may comprise two-dimensional or three-dimensional quantum structures such as quantum wires, quantum dashes, or zero-dimensional structures such as quantum dots. A layer of the active layer structure forming a quantum well or comprising any of those quantum structures may be referred to as a “quantum structure layer”.

The optical functionalities of the DFB laser diode 130 and the SOA 140 may be adjusted by the selection of the materials of the lower cladding layer 114, the upper cladding layer 115, and the active layer structure 111. One optical parameter affecting the optical functionalities is the refractive index.

Depending on the configuration and materials of the cladding layers and the active layer structure, the lower cladding 114 layer has at least one lower cladding refractive index nₗ, the upper cladding 115 layer has at least one upper cladding refractive index nᵤ, and the active layer structure 111 has at least one active refractive index nₐ. A layer or a layered structure having “at least one” refractive index refers to the possibility that such layer or layer structure comprises more than one material, or one material with different doping levels, and thus several refractive indices.

To provide appropriate optical functionalities, the materials of those cladding layers and the active layer structure may be selected so as to provide the at least one lower cladding refractive index nₗ and at least one upper cladding refractive index nᵤ to be lower than the at least one active refractive index nₐ. Further, the cap layer 116 may have at least one cap refractive index n_{c} higher than the lower cladding refractive index nₗ and the upper cladding refractive index nᵤ. In the case of a layer or a layer structure comprising more than one refractive index, all those refractive indices may be in accordance with the conditions specified above.

It is to be noted that in addition to those layers and structures discussed above with reference to FIG. 1, the photonic semiconductor device 100 of FIG. 1 may comprise any appropriate further layers, sub-layers, and/or structures necessary, useful, or effective for the properties and/or operation of the photonic semiconductor device 100. For example, electrical contacts of the photonic semiconductor device 100 may be implemented in any appropriate manner.

The details of the layer structure of the photonic semiconductor device 100 may be implemented in accordance with any of the examples and embodiments discussed below with reference to FIG. 2. On the other hand, any of those examples and embodiments may be utilized to implement photonic semiconductor devices in accordance with any of those discussed above with reference to FIG. 1.

In the photonic semiconductor device 200 of FIG. 2, each of the lower cladding layer 214 and the upper cladding layer 215 comprises and may be made of aluminum gallium arsenide AlGaAs.

In the example of FIG. 2, the lower cladding layer may be doped to be of n-type conductivity, and the upper cladding layer may be doped to be of p-type conductivity. The active layer structure 211 may comprise layers of undoped InAs and InGaAs. Thereby, a p-i-n junction or diode may be formed by the cladding layers 214, 215 and the active layer structure 211.

The active layer structure 211 of the photonic semiconductor device 200 comprises a plurality of quantum structure layers 212 made of InAs and/or InGaAs each comprising quantum dots QD 213. Those layers may thus be considered as quantum dot layers or layers of quantum dots. In the example of FIG. 2, adjacent quantum structure layers are separated by intermediate buffer layers 218.

In other embodiments, the active layer structure of a photonic semiconductor device may comprise and can be made of indium arsenide InAs, gallium arsenide GaAs, and/or indium gallium arsenide InGaAs, the active layer structure comprising one or more quantum structure layers. For example, there may be at least one quantum-dimensional structure formed of InGaAs forming on quantum well, and quantum dots formed of InAs embedded within such quantum well.

There are three quantum dot layers 212 in the active layer structure 211 of the example of FIG. 2. In other embodiments, any appropriate numbers of quantum dot layers may be used. There may be, for example, any number of 1 to 10.

The quantum dots 213 of the active layer structure 211 may have a plurality of different sizes. First, the quantum dots of one single quantum dot layer may have a plurality of sizes constituting a quantum dot size distribution as well as an average quantum dot size. Further, the quantum dot size distribution as well as the average quantum dot size may vary between different quantum dot layers. Thus, the size distribution or the average size of the quantum dots of one quantum dot layer may differ from the size distribution or the average size of the quantum dots, respectively, of one or more of the other quantum dot layers.

The size of a quantum dot may affect the wavelength at which stimulated emission of radiation in the laser diode and light amplification in the SOA takes place. Thereby, light generation or emission in the laser active region comprising quantum dots of different sizes may take place at a plurality of wavelengths. Correspondingly, amplification of light in the amplifier active region formed by the same active layer structure as the laser active region may take place at the same plurality of wavelengths.

In a photonic semiconductor device incorporating a heterostructure producing a plurality of wavelengths, an array of a plurality of DFB laser diodes may each have one or two distributed Bragg reflectors configured to produce a maximum reflectance at a center wavelength differing from the center wavelengths at which the surface corrugated gratings serving as DBRs of the other DFB laser diodes have their maximum reflectance. Thereby, each DFB laser diode may be adjusted to emit light at one of the center wavelengths. Thereby, the surface corrugated grating(s) may be considered to be configured to select the center wavelength which is emitted out of each of the laser diodes.

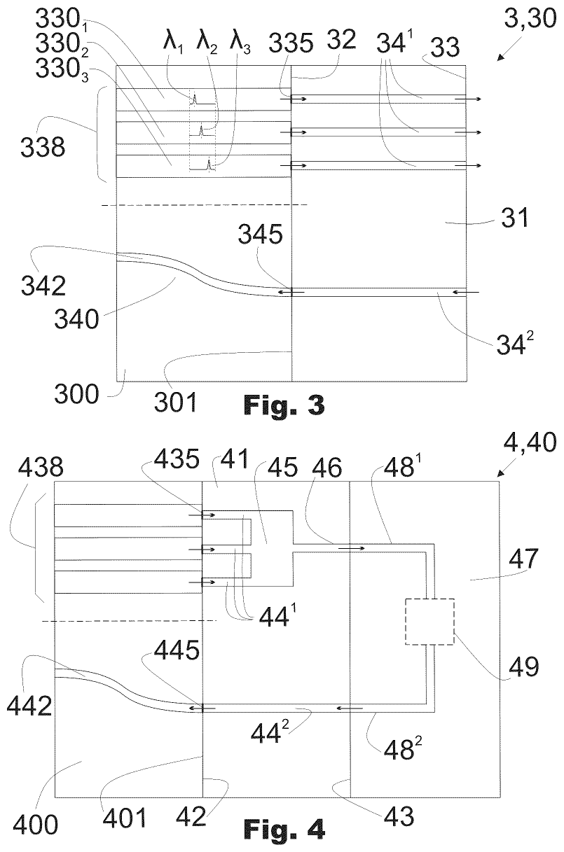

An example of such array 338 of three DFB laser diodes 330 is illustrated in FIG. 3. Each of the three DFB laser diodes 330₁, 330₂, 330₃ of the photonic semiconductor device 300 emits light at a specific center wavelength λ₁, λ₂, λ₃. The SOA 340 of the photonic semiconductor device 300, sharing the common active layer structure with the DFB laser diodes 330, correspondingly amplifies light at the same center wavelengths. The DFB laser diodes and the SOA of the photonic semiconductor device 300 may be in accordance with any of those discussed above with reference to FIG. 1 or FIG. 2

The photonic semiconductor device 300 OF FIG. 3 is a part of an optical assembly 30 comprising also an optical coupling element 31.

The optical coupling element 31 has a first coupling surface 32 facing towards the optical interface edge 301 of the photonic semiconductor device 300, and an opposite second coupling surface 33. The first coupling surface faces towards the optical interface edge 301 of the photonic semiconductor device 300. The optical coupling element 31 comprises three first waveguides 34¹ configured and positioned to receive light transmitted out of the optical output facet(s) 335 of the DFB laser diodes 330 and transmit it from the first coupling surface 32 to the second coupling surface 33 and thereby out of the optical coupling element 31.

The optical coupling element may comprise, for example, a glass body, in which the waveguides are formed, for example, by direct laser writing.

The optical coupling element 31 further comprises a second waveguide 34² configured and positioned to receive light and transmit it from the second coupling surface 33 to the first coupling surface 31 and thereby out of the second waveguide via the optical input facet 345 into the SOA 340.

Using an optical coupling element such as that of FIG. 3 to form an optical assembly comprising a photonic semiconductor device and the optical coupling element, the photonic semiconductor device may be optically coupled, for example, to a photonic integrated circuit PIC with a one-side coupling configuration. In a one-side optical coupling configuration, optical input and output interfaces of the PIC lie on the same side of the PIC.

The waveguides 34¹, 34² of the optical coupling element may be formed so as to be adapted to the positions of the optical output facets 335 of the laser diodes 330 and the optical input facet 345 of the SOA 340 as well as to the positions of waveguides of the PIC. For example, an optical coupling preform may first be positioned and mounted adjacent to the optical interface edge 301 of the photonic semiconductor device 300, and the waveguides 34¹, 34² may then be formed therein in accordance with the positions of the optical output facets 335 of the laser diodes 330 and the optical input facet 345 of the SOA 340 as well as expected positions of the waveguides of the PIC. Thereby, the optical coupling element 31 may facilitate achievement of a proper alignment and thereby an appropriate optical coupling between the output facets 335 of the DFB laser diodes 330 as well as the optical input facet 345 of the SOA, and the input and output waveguides of the PIC.

The photonic semiconductor device 40 of FIG. 4 may be in accordance with that discussed above with reference to FIG. 3.

The optical coupling element 41 of the optical assembly 40 of FIG. 4 distinguishes from those discussed above with reference to FIG. 3 in that it comprises a combiner 45 which combines the three first waveguides 44¹ into one common waveguide 46. In other embodiments, optical coupling elements without any combiner, such as those discussed above with reference to FIG. 3, may be used.

The optical assembly 40 of FIG. 4 comprises, in addition to a photonic semiconductor device 400 and an optical coupling element 41, also a PIC 47. The first coupling surface 42 of the optical coupling element faces towards the optical interface edge 401 of the photonic semiconductor device 400, and the opposite second coupling surface 43 thereof faces towards the PIC 47.

The PIC comprises an input waveguide 48¹, and an output waveguide 48², and one or more operational optical elements, modules, or devices 49 therebetween. Such optical element(s), module(s), or device(s) may comprise, for example, one or more optical modulators, such as a Mach-Zehnder modulator or a ring modulator. In addition to, or instead of, modulator(s), the PIC my comprise any other appropriate other type(s) of optical operational element(s), module(s), or device(s).

In other embodiments with an optical coupling element without any combiner, the PIC may comprise a plurality of input waveguides.

The input waveguide 48¹ is positioned and configured to receive light transmitted out of the common waveguide 46 of the optical coupling element 41. The output waveguide 48² is positioned and configured to transmit light out of it to the second waveguide 44² of the optical coupling element 41.

Thereby, the optical assembly 40 may serve for emitting light signals by the DFB laser diodes 430, manipulate the thereby emitted light signals by the PIC 47, and then amplify the thereby manipulated light signals by the SOA 440, from which the amplified light signals may be transmitted further to any appropriate purpose.

Using in an optical assembly an optical coupling element between a photonic semiconductor device and a PIC, accurate alignment between the DFB laser diodes as well as the SOA of the photonic semiconductor device and the waveguides of the PIC may be achieved.

For example, the photonic semiconductor device and the PIC may be positioned, separated by an optical coupling preform therebetween, with the optical interface edge of the photonic semiconductor device facing towards the PIC. The optical output facets and the optical input facets of the photonic semiconductor device may then be preliminarily aligned with the input and output waveguides of the PIC. Thereafter, possible misalignments may be determined or measured, and the first and second waveguides as well as possible combiner(s) and common waveguides may be defined and formed in the optical coupling preform so as to compensate the effects of possible misalignments.

An optical coupling preform or a complete optical coupling element may comprise a body mostly or entirely formed of, for example, a glass or a plastic material where waveguides with refractive index differing from that of the surrounding glass or plastic material may be formed.

In the examples of FIGS. 3 and 4, the photonic integrated circuits 300, 400 comprise arrays 338, 438 of three DFB laser diodes 330, 430 and one SOA 340, 440.

In other embodiments, arrays of any appropriate number of DFB laser diodes may be implemented and used in photonic integrated circuits of optical assemblies. On the other hand, optical assemblies may be implemented where the photonic semiconductor device comprises, instead of an array of DFB laser diodes, one single DFB laser diode. Irrespective of the number of DFB laser diodes therein, photonic semiconductor devices of optical assemblies may comprise any number of SOAs: one SOA or a plurality of SOAs which may be arranged in an array. In all embodiments, the number of first and second waveguides of the coupling element may be selected in accordance with the number of the DFB laser diodes and the SOAs.

Any of the optical assemblies 30, 40 of FIGS. 3 and 4 may be incorporated in, comprised by, or serve as a part of, an optical transceiver. The drawings of those FIGs. may thereby be considered representing partial illustrations of optical transceivers 3, 4.

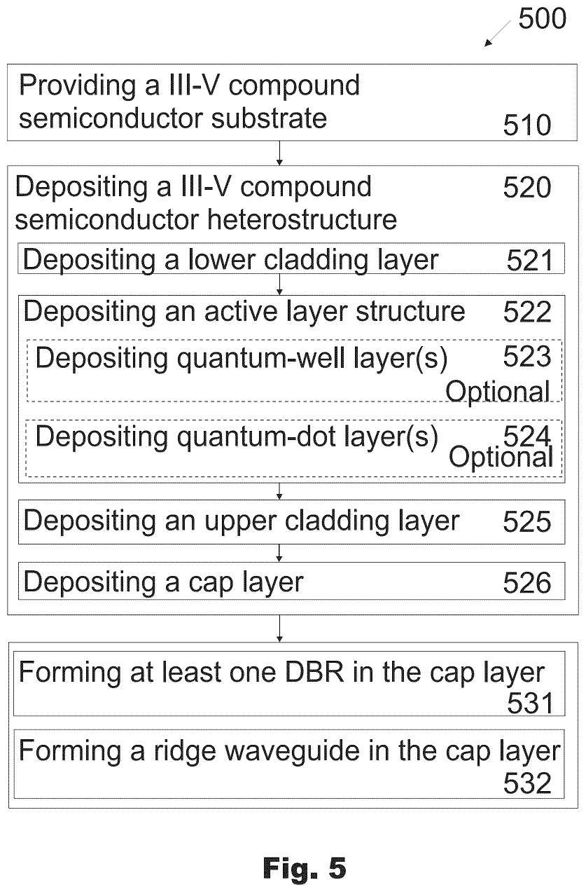

The method 500 of FIG. 5 may be used to manufacture photonic semiconductor devices in accordance with any of those discussed above. As discussed above, such device comprises an array of at least two distributed feedback (DFB) laser diodes having a laser active region, and at least one semiconductor optical amplifier (SOA) having an amplifier active region.

The method 500 starts by providing, in operation 510, a III-V semiconductor substrate.

A III-V semiconductor heterostructure is deposited on the substrate in operation 520 as discussed in more detail below.

In operation 521, a lower cladding layer is formed on the substrate. Thereafter, an active layer structure is formed on the lower cladding layer in operation 522, whereafter an upper cladding layer is formed on the active layer structure in operation 525. Finally, a cap layer is formed on the upper cladding layer in operation 526.

As part of the active layer structure deposition, one or more quantum well layers and/or one or more quantum dot layers may be deposited in operations 523, 524.

Examples of the details of the cladding layers and the active layer structure are discussed above with reference to FIGS. 1 and 2.

The active layer structure is manufactured so as to form the laser active region and the amplifier active region of the photonic semiconductor device.

The deposition operations may take place in and be carried out using any appropriate deposition equipment, such as Molecular Beam Epitaxy (MBE) or Metal-Organic Chemical Vapor Deposition (MOCVD). The deposition operations may take place in a deposition chamber in vacuum conditions.

As the laser active region of the DFB laser diode(s) and the amplifier active region of the SOA(s) are formed by the same active layer structure, all the deposition operations of the active regions may be advantageously carried out in a single deposition process within the same deposition chamber. Also the cap layer may be deposited in the same deposition process.

Advantageously, no additional growth processes are thereby needed but all the layers of the DFB laser diodes and the SOA(s) may be formed in the same single epitaxial growth or deposition process. This may greatly simplify the manufacturing process in comparison to ones requiring additional overgrowth after the initial epitaxial process to complete the semiconductor heterostructure.

One or more surface corrugated gratings are formed in the cap layer for each DFB laser diode of the photonic semiconductor substrate in operation 531. Correspondingly, a ridge waveguide is formed in the cap layer for each SOA of the photonic semiconductor substrate in operation 532.

A surface corrugated grating may comprise, for example, an array of indentations or hollows formed in the cap layer by etching.

Also a ridge waveguide may be formed in the cap layer by removing at least part of the cap layer outside the designed ridge waveguide.

To facilitate the etching, a stop layer may be deposited during the deposition process before the deposition of the cap layer. With a suitably selected material thereof, the stop layer may serve for stopping the etching process, thereby improving the etching process controllability.

The photonic semiconductor device may be manufactured so as to have a parallel configuration wherein the optical output facets of the at least two DFB laser diodes and the optical input facets of the at least one SOA lie on the optical interface edge.

It will be understood that the benefits and advantages described above may relate to one embodiment or example or may relate to several embodiments or examples. The embodiments and examples are not limited to those that solve any or all of the stated problems or those that have any or all of the stated benefits and advantages. It will further be understood that reference to ‘an’ item refers to one or more of those items.

Wherever in this specification a device, component, element, member, or another entity is specified being “configured to” “for” a specific operation, such entity may be considered being “for” carrying out that operation.

The term “comprising” is used in this specification to mean including the feature(s) followed thereafter, without excluding the presence of one or more additional features.

1. A photonic III-V semiconductor device comprising at least one distributed feedback (DFB) laser diode having a laser active region, and at least one semiconductor optical amplifier (SOA) having an amplifier active region,
wherein the III-V semiconductor device comprises a III-V semiconductor heterostructure formed on a III-V semiconductor substrate, the III-V semiconductor heterostructure comprising an active layer structure between a lower cladding layer and an upper cladding layer; the active layer structure forming the laser active region and the amplifier active region;
the semiconductor device having an optical interface edge; wherein the at least one DFB laser diode comprises an optical output facet, and the at least one SOA comprises an optical input facet; the at least one DFB laser diode and the at least one SOA being positioned in parallel with the output facet and the input facet lying on the optical interface edge.

2. A photonic III-V semiconductor device as defined in claim 1, wherein the III-V semiconductor heterostructure further comprises a cap layer on the upper cladding layer; each of the at least one DFB laser diode has at least one surface corrugated grating configured to serve as a distributed Bragg reflector (DBR); and the at least one SOA has a ridge waveguide; the surface corrugated gratings and the ridge waveguide being formed in the cap layer.

3. A photonic III-V semiconductor device as defined in claim 2, wherein the ridge waveguide comprises at least one bent section.

4. A photonic III-V semiconductor device as defined in claim 1, comprising a cap layer on the upper cladding layer, wherein the lower cladding layer has a lower cladding refractive index, the upper cladding layer has an upper cladding refractive index, and the cap layer has a cap refractive index higher than the lower cladding refractive index and the upper cladding refractive index.

5. A photonic III-V semiconductor device as defined in claim 1, wherein the active layer structure comprises at least one quantum structure layer comprising at least one quantum well, quantum dots, quantum wires, and/or quantum dashes.

6. A photonic III-V compound semiconductor device as defined in claim 1, wherein the III-V semiconductor comprises gallium arsenide GaAs; the active layer structure comprising indium arsenide InAs and/or indium gallium arsenide InGaAs; the lower cladding layer comprising AlGaAs, and the upper cladding layer comprising AlGaAs.

7. A photonic III-V semiconductor device as defined in claim 6, wherein the active layer structure comprises at least one quantum structure layer comprising indium arsenide InAs, gallium arsenide GaAs, and/or indium gallium arsenide InGaAs.

8. A photonic III-V semiconductor device as defined in claim 7, wherein the at least one quantum structure layer comprises at least one layer of quantum dots.

9. A photonic III-V semiconductor device as defined in claim 8, wherein the at least one layer of quantum dots comprises a plurality of superposed layers of quantum dots.

10. A photonic III-V semiconductor device as defined in claim 9, wherein the quantum dots of different layers of the plurality of superposed layers of quantum dots have different size distributions.

11. A photonic III-V compound semiconductor device as defined in claim 1, wherein the at least one DFB laser diode comprises an array of a plurality of DFB laser diodes.

12. A photonic III-V semiconductor device as defined in claim 11, wherein the laser active region is configured to generate light at a wavelength range, and each of the DFB lasers of the plurality of DFB laser diodes has at least one surface corrugated grating configured to serve as a distributed Bragg reflector (DBR), configured to produce a maximum reflectance at a center wavelength differing from the center wavelengths at which the surface corrugated grating(s) of each of the other DFB laser diodes of the plurality of DFB laser diodes produces its maximum reflectance, the at least one SOA being configured to amplify each of the center wavelengths.

13. An optical assembly comprising a photonic III-V semiconductor device as defined in claim 1, and an optical coupling element having a first coupling surface and an opposite second coupling surface, the first coupling surface being faced towards the optical interface edge; the optical coupling element comprising at least one first waveguide configured and positioned to receive light transmitted out of the optical output facet(s) and transmit it from the first coupling surface to the second coupling surface and thereby out of the optical coupling element, and at least one second waveguide configured and positioned to receive light and transmit it from the second coupling surface to the first coupling surface and thereby out of the optical waveguide to the optical input facet(s).

14. An optical assembly as defined in claim 13, wherein the at least one DFB laser diode comprises an array of a plurality of DFB laser diodes, and the at least one first waveguide comprises a plurality of first waveguides.

15. An optical assembly as defined in claim 14, wherein the optical coupling element comprises a combiner configured to combine two or more of the plurality of first waveguides.

16. An optical assembly as defined in claim 13, further comprising a photonic integrated circuit (PIC) configured and positioned to receive the light transmitted out of the optical coupling element by the first waveguide(s), and to transmit it back to the optical coupling element to the second waveguide(s) thereof.

17. An optical transceiver or an optical engine comprising an optical assembly as defined in claim 13.

18. A method for manufacturing a photonic III-V semiconductor device comprising at least one distributed feedback (DFB) laser diode having a laser active region, and at least one semiconductor optical amplifier (SOA) having an amplifier active region, the method comprising the operation of
depositing, on a III-V semiconductor substrate, a III-V semiconductor heterostructure comprising an active layer structure superposed between a lower cladding layer and an upper cladding layer; the active layer structure forming the laser active region and the amplifier active region; the semiconductor device having an optical interface edge, wherein the at least one DFB laser diode comprises an optical output facet, and the at least one SOA comprises an optical input facet; the at least one DFB laser diode and the at least one SOA being manufactured so as to be positioned in parallel with the output facet and the input facet lying on the optical interface edge.

19. A method as defined in claim 18, the method comprising the operations of
depositing a cap layer on the upper cladding layer; and
forming, in the cap layer, at least one surface corrugated grating configured to serve as a distributed Bragg reflector (DBR) for the at least one DFB laser diode, and a ridge waveguide for the at least one SOA.

20. A method as defined in claim 18, wherein the at least one DFB laser comprises an array of a plurality of DFB lasers.
